(19) United States
(12) Patent Application Publication
(10) Pub. No.: US 2007/0074970 A1
(43) Pub. Date: Apr. 5, 2007

(54) DEVICE AND METHOD OF MANUFACTURING SPUTTERING TARGETS

(75) Inventors: Clifford C. Purdy II, Reno, NV (US); Gregory M. Howard, Reno, NV (US)

Correspondence Address: IAN F. BURNS & ASSOCIATES, P.O. BOX 71115, RENO, NV, 89570, US

(73) Assignee: CP Technologies, Inc., Reno, NV (US)

(21) Appl. No.: 11/533,344

(22) Filed: Sep. 19, 2006

Related U.S. Application Data
(60) Provisional application No. 60/719,084, filed on Sep. 20, 2005.
(60) Provisional application No. 60/766,368, filed on Jan. 13, 2006.
(60) Provisional application No. 60/783,588, filed on Mar. 16, 2006.

(51) Int. Cl. C23C 14/00

(52) U.S. Cl. 204/298.12

(57) ABSTRACT

The present invention comprises an apparatus for manufacturing a sputtering target that has a crucible for holding a liquid material. The crucible has a discharge opening. A positioning mechanism is mounted adjacent the crucible. A substrate is held by the positioning mechanism. The positioning mechanism moves the substrate such that the material is deposited onto the substrate. A method of manufacturing a sputtering target is also disclosed. The method includes melting an material and discharging the material through a nozzle. A substrate is moved adjacent the nozzle such that the material is deposited onto the substrate.

### CROSS REFERENCE TO RELATED APPLICATIONS

This application claims priority to U.S. provisional patent application Ser. Nos. 60/719,084, filed Sep. 20, 2005 and entitled, “Device and Method of Manufacturing Sputtering Targets,” and to Ser. No. 60/766,368, filed Jan. 13, 2005 and entitled, “Device and Method of Manufacturing Sputtering Targets,” and to 60/766,368, filed Jan. 13, 2005 and entitled, “Device and Method of Manufacturing Sputtering Targets”. The contents of which are herein incorporated by reference.

### BACKGROUND

1. Field of the Invention

The present invention relates to an apparatus and method that is used to manufacture and use sputtering targets. In particular, the invention relates to an apparatus and method of manufacturing and using sputtering targets that are formed from liquid materials.

2. Description of the Related Art

Sputtering can be used to deposit one or more thin film layers onto a target substrate. Sputtering is a process that dislodges atoms from the surface of a sputtering target by collision with high-energy particles in order to deposit a metallic film on a substrate. Sputtering targets are typical used to produce various coated substrates that are used in various products, such as semiconductors, touch panels, liquid crystal displays, energy saving glass and others.

The atoms of a material to be deposited on the substrate are physically removed from the sputtering target surface by ion bombardment. Sputtering uses an evacuated chamber, a target cathode and a substrate anode. The evacuated chamber is typically filled with argon gas or other inert gas. The electric field inside a sputtering chamber accelerates a stream of electrons into the argon gas. The electrons collide with the argon atoms producing positive argon ions and more electrons. These argon ions are then accelerated by the electric field and impact the cathode or sputtering target. The impact of the argon atom results in the ejection of one or more sputtering target atoms. The target atoms scatter in all directions while some of the target atoms will travel in the direction of the substrate anode and will condense on the surface of the substrate producing a thin film.

In some applications, it is important that the film of deposited material have a particular stoichiometery. In the production of thin film solar panels, for example, it is important that the film have particular relative proportions of certain metals. If the proportions do not fall within certain ranges, the panels may not function or they may have decreased efficiency.

Typical sputtering targets have a base substrate that is covered with the material that is desired to be deposited by the sputtering process. Sputtering targets can have various shapes. One such shape is a cylinder. A cylindrical target can be rotated during the sputtering process such that material is removed uniformly over the whole target. A stationary target that is composed of more than one element or phase can remove target material at different rates resulting in a non-uniform or inhomogeneous deposited coating.

Sputtering targets are typically produced by either casting an alloy into the desired shape or by plasma or flame spraying the desired material onto a base substrate. However, for various substances that melt at relatively low temperatures, such as Copper, Indium and Gallium, casting and plasma spraying can result in a sputtering target that has a non-uniform or inhomogeneous deposited coating. The resulting deposited coating may have an undesirable chemical composition or the deposited coating may contain the incorrect proportion of material phases. Another problem associated with prior art techniques for manufacturing sputtering targets is the formation of voids, fissures and inconsistent densities on the target.

Another problem associated with low melting point materials is that they tend to have poor adhesion between the target substrate and the outer deposited material. The bond between the deposited material layer and the target substrate must provide good mechanical strength and thermal and electrical conductivity during the sputtering process. Flaws in the bonding can cause arcing or delaminating during the sputtering process.

There exists an unmet need for an apparatus and method that produces sputtering targets that have homogeneous deposited materials and that have good adhesion between the deposited material and the target substrate. Furthermore, there exists an unmet need for an apparatus and method that produces a sputtering target with fewer voids and fissures and greater density. In addition, there exists an unmet need for an apparatus and method that produces sputtering targets with a uniform stoichiometry.

### SUMMARY

Advantages of One or More Embodiments of the Present Invention

The various embodiments of the present invention may, but do not necessarily, achieve one or more of the following advantages:

the ability to coat a substrate with a liquid material or materials to manufacture a sputtering target;

the ability to apply a stream of liquid material onto a substrate;

the ability to translate a substrate while a applying a stream of liquid material;

the ability to rotate a substrate while applying a stream of liquid material;

the ability to produce a sputtering target with fewer voids or fissures;

the ability to produce a sputtering target with higher density target material;

the ability to produce a sputtering target with has a uniform desired stoichometery;

the ability to efficiently and effectively control cooling rate of material deposited on a target substrate;

the ability to apply a liquid material to a sputtering target;

the ability to melt and hold a liquid material;

the ability to translate a target substrate;

the ability to coat a substrate with a liquid material; and

the ability to manufacture a sputtering target that has a target material with components that have different melting temperatures.

These and other advantages may be realized by reference to the remaining portions of the specification, claims, and abstract.

### BRIEF DESCRIPTION

The present invention comprises an apparatus for manufacturing a sputtering target that includes a crucible for holding a liquid material. The crucible has a discharge opening. A positioning mechanism is mounted adjacent the crucible. A substrate is held by the positioning mechanism. The positioning mechanism moves the substrate such that the material is deposited onto the substrate.

The present invention further comprises a method of manufacturing a sputtering target that includes melting a material and discharging the material through a nozzle or oriface. A substrate is moved adjacent the nozzle such that the material is deposited onto the substrate.

The above description sets forth, rather broadly, a summary of one embodiment of the present invention so that the detailed description that follows maybe better understood and contributions of the present invention to the art may be better appreciated. Some of the embodiments of the present invention may not include all of the features or characteristics listed in the above summary. There are, of course, additional features of the invention that will be described below and will form the subject matter of claims. In this respect, before explaining at least one embodiment of the invention in detail, it is to be understood that the invention is not limited in its application to the details of the construction and to the arrangement of the components set forth in the following description or as illustrated in the drawings. The invention is capable of other embodiments and of being practiced and carried out in various ways. Also, it is to be understood that the phraseology and terminology employed herein are for the purpose of description and should not be regarded as limiting.

### BRIEF DESCRIPTION OF THE DRAWINGS

The embodiments of the present invention are shown in the drawings, wherein:

FIG. 1 is substantially a front perspective view of a cylindrical sputtering target produced in accordance with one embodiment of the present invention.

FIG. 2 is substantially a side view of FIG. 1.

FIG. 3 is substantially an overall perspective view of one embodiment of an apparatus for manufacturing sputtering targets in accordance with the present invention.

FIG. 4 is substantially an enlarged perspective view of the furnace assembly of FIG. 3.

FIG. 5 is substantially a partial side view of one embodiment of an apparatus for manufacturing sputtering targets, including a crucible assembly and an actuator assembly.

FIG. 6 is substantially an enlarged cross-sectional view of the crucible assembly of FIG. 3.

FIG. 7 is substantially a partial front view of the actuator assembly of FIG. 5 with the target cooling housing removed.

FIG. 8 is substantially a diagrammatic view of a control system in accordance with one embodiment of the present invention.

FIG. 9 is substantially a flow chart of a method of manufacturing a sputtering target in accordance with one embodiment of the present invention.

FIG. 10 is substantially an alternative embodiment of a crucible assembly.

FIG. 11 is substantially an alternative embodiment of a crucible assembly.

FIG. 12 is substantially an enlarged view of an outlet pipe of FIG. 11.

FIG. 13 is substantially another alternative embodiment of a crucible assembly.

FIG. 14 is substantially yet another embodiment of a crucible assembly.

FIG. 15 is substantially an alternative embodiment of a crucible assembly.

FIG. 16 is substantially an alternative embodiment of a crucible assembly.

FIG. 17 is substantially a diagrammatic view of a sputtering system that can be used with the sputtering target of the present invention.

### DESCRIPTION OF THE EMBODIMENTS

In the following detailed description of the embodiments, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

Sputtering Target

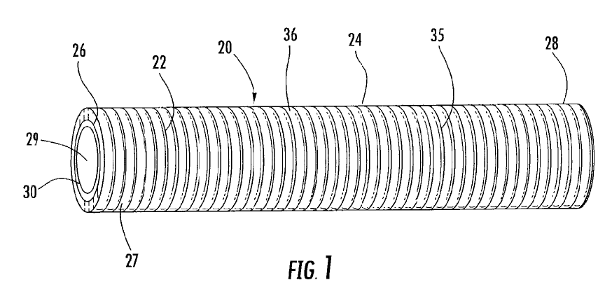

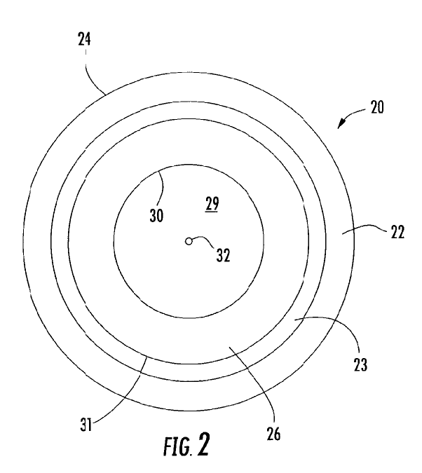

The present invention comprises a sputtering target, generally indicated by reference number 20. Referring to FIGS. 1 and 2, a cylindrical sputtering target 20 is shown. Sputtering target 20 can have an outer covering of a deposited material 22. Deposited material 22 can be selected from a wide variety of materials including various elements, compounds and mixtures. Target 20 may be made in a large variety of other shapes, such as spheres, cones, squares, circles and planar shapes.

In one embodiment, deposited material 22 can be a material of several metals that melt at relatively low temperature, such as Copper, Indium and Gallium. Deposited material 22 may comprise any combination of percentages of Copper, Indium and Gallium. Deposited material 22 may further comprise any combination of percentages of chosen metals. In another embodiment, deposited material 22 may be a mixture of an epoxy and metal or other particles.

Sputtering target 20 may include an outer surface 24, end 27 and end 28. Sputtering target 20 has a cylindrical target substrate 26. Target substrate 26 can be formed from many different materials in many shapes, such as stainless steel, brass, aluminum, quartz, ceramic, or many other materials. Other metals for substrate 26 may also be utilized. Deposited material 22 is placed onto substrate 26 as will be further explained below.

In one embodiment an adhesion promoter 23 can be deposited between substrate 26 and deposited material 22. Adhesion promoter 23 increases the attachment strength of deposited material 22 to substrate cylinder 26 and prevents peeling or de-lamination. In one embodiment, adhesion promoter 23 is indium. Alternatively, adhesion promoter 23 may be omitted for certain materials that have good adhesion strength.

Substrate 26 has a bore 29 that extends through the cylinder, an inner surface 30 and a central longitudinal axis of rotation 32. Substrate 26 may be rotated around the axis of rotation 32. Substrate 26 is further adapted to be translated or moved linearly parallel to the length of substrate 26. A deposited stream 35 can be deposited on outer surface 24. Deposited stream 35 continuously covers and builds up on outer surface 24 in order to form deposited material 22. Deposited stream 35 can form a helical pattern 36 on outer surface 24 as substrate 26 is rotated and translated.

Deposition Apparatus

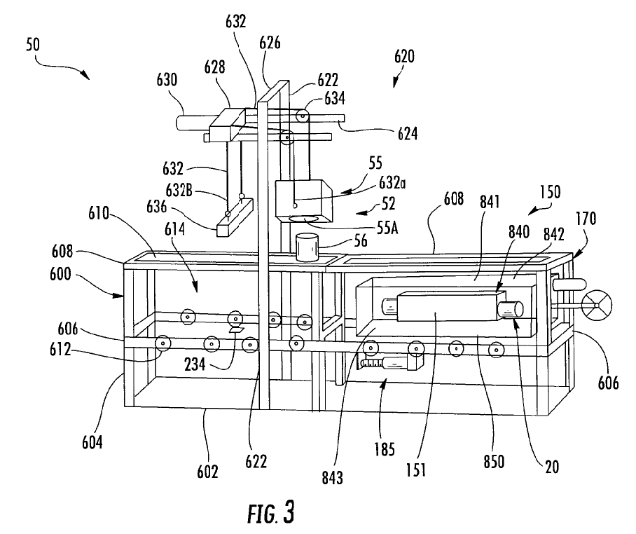

The present invention further comprises a deposition apparatus, generally indicated by reference number 50. Referring to FIGS. 3-7, deposition apparatus 50 can include a frame 600 that supports a furnace assembly 620, a crucible assembly 52 and a positioning mechanism or actuator assembly 150.

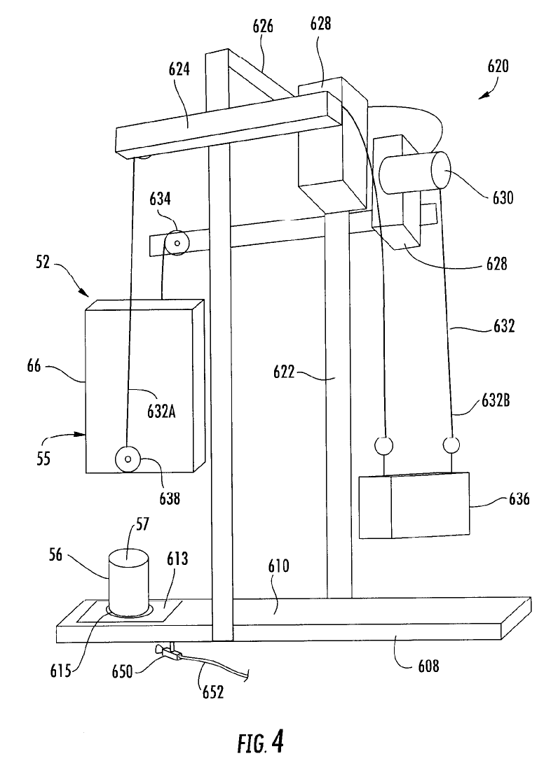

With specific reference to FIGS. 3 and 4, frame 600 can include a floor portion 602, vertical beams 604, center beam or rail 606, top beam 608. A top plate 610 can be mounted to top beam 608. Top plate 610 has a hole 611, a seal 613 and a raised insulation portion 615. Frame 600 can be formed from steel tubing or I-beams that are welded or bolted together to form frame 600. Frame 600 can form a cavity 614. Several wheels or bearings 612 can be mounted to center beam 606 and extend partially into cavity 614.

A holder or housing 840 includes an enclosure 842 mounted on a table 850. Enclosure 842 has sides 843. Enclosure 842 can be formed form a transparent material such as polycarbonate. Housing 840 can support and hold target 20. Housing 840 may be sealed and filled with an inert gas.

Table 850 rests on bearings 612 that allow housing 840 to translate in an out of cavity 614. Table 850 can have a top surface 852 and a bottom surface 853. Housing 840 can have a cavity 841 that contains sputtering target 20. A target cooling housing 151 can be mounted inside of housing 840. A rotary actuator assembly 170 can be mounted to table 850 in order to rotate sputtering target 20. A translational actuator assembly 185 can be mounted between table 850 and frame 600 in order to move housing 850 and target 20 in and out of cavity 614.

A furnace assembly 620 can be mounted to frame 600. Furnace assembly 620 can include a pair of vertical support beams 622 that are mounted to frame 600 and extend above top plate 610. A pair of horizontal support beams 624 can be mounted to vertical support beams 622. A top bar 626 connects between vertical support beams 622.

A gear box 628 with internal pulley (not shown) is mounted between horizontal support beams 624. Actuator motor 630 is mounted to gear box 628. A pair of pulleys 634 is mounted to the other end of horizontal support beams 624. A pair of cables 632 passes over pulleys 634 and through the internal pulleys in gear box 628. Cables 632 have ends 632A and 632B. Counterweight 636 is attached to cable ends 632B. Cable ends 632A are attached to furnace case 55 through cable attachment 638. Actuator motor 630 can raise and lower the furnace over crucible 56.

Case 55 can have a cavity 55A. Crucible 56 is mounted to top plate 610 on top of insulation portion 615. Insulation portion 615 can be formed from a ceramic material. Crucible 56 has a crucible cavity 57. Crucible 56 would be formed from a heat resistant refractory material such as a ceramic, silicon carbide or graphite. Case 55 can be covered with insulation 66. A camera 650 can be mounted below top beam 608 in order to view material leaving crucible 56. A cable 652 would be connected with a remote monitor (not shown) for remote observation of the deposition apparatus in operation. Actuator 630 and gear box 628 are adapted to raise and lower furnace case 55 over crucible 56. Electric cables (not shown) would be connected to furnace case 55 in order to supply electric power to the furnace.

A seal or sealing material 613 is mounted top plate 610 and is located between top plate 610 and furnace case 55. Seal 613 can be formed from a high temperature sealing material. Seal 613 prevents oxygen from entering cavity 55A and prevents inert gases that are provided to cavity 55A from leaking out.

An impeller assembly (not shown in FIGS. 3 and 4 and discussed below) can be mounted on top of case 55 in order to mix the liquid contents of crucible 56.

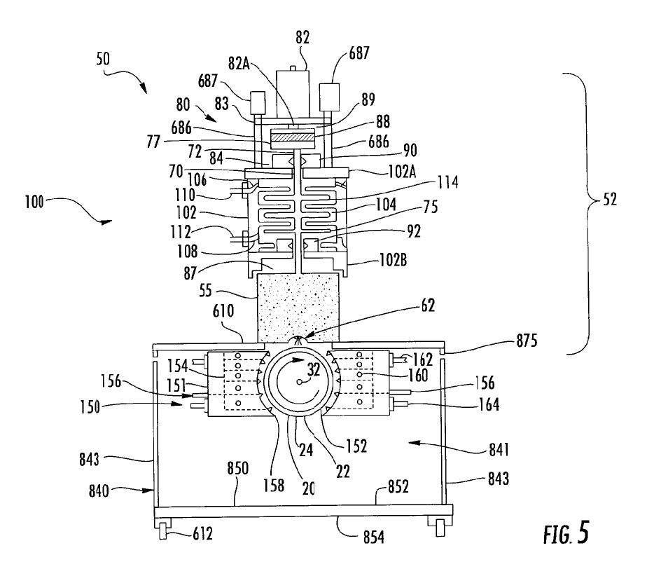

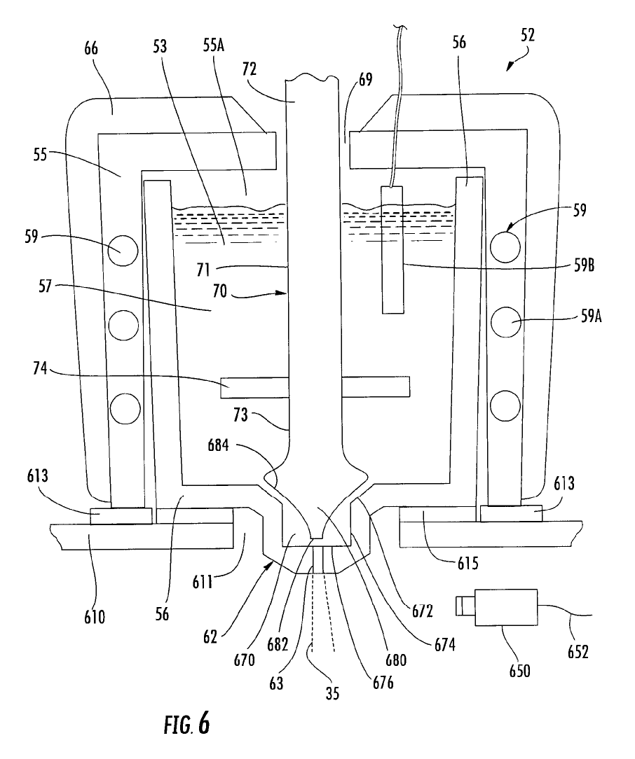

With specific reference to FIGS. 5 and 6, crucible assembly 52 includes a furnace case 55 that contains a crucible 56. Case 55 can be formed from a metal such as steel. Case 55 has a cavity 55 that is adapted to fit over crucible 56. Crucible 56 would be formed from a heat resistant refractory material such as a silicon carbide. Crucible 56 may be cup shaped and has a crucible cavity 57.

The crucible assembly may be constructed to withstand relatively high temperatures. For instance, the crucible assembly may withstand temperatures exceeding 1,100 degrees Celsius. Crucible 56 is adapted to hold a liquid material 53 in a liquid state. A variety of solid materials can be placed in crucible 56 to be melted and then mixed.

At least one heat source 59 is provided for keeping the liquid material 53 at an operating temperature. The operating temperature is generally above the melting temperature of the material and it provides the liquid material with predetermined properties, such as a predetermined level of viscosity.

In some embodiments, it may be desirable to control the atmosphere above liquid material 53 in order to further control unwanted elements in the liquid material such as oxygen or hydrogen. In these embodiments, all or part of deposition apparatus 50 may be placed in to a controlled atmosphere chamber (not shown). The chamber can be filled with a desired liquid or gas, such as argon or nitrogen, or a vacuum could be provided in the chamber.

Heat source 59 can comprise several electric heaters 59A that are mounted within case 55. Heat source 59 can also comprise one or more cartridge 59B heaters that are placed directly in contact with liquid material 53. The electric heaters are adapted to be connected with a source of electrical power. Heat source 59 can also be a heat transfer device, such as a heat exchanger, or other heat source, such as radio frequency heaters.

Crucible 56 has a discharge opening or nozzle 62 including a trough 670 located at the bottom of the crucible. Trough 670 has a seat portion 672 and walls 674 and 676. Nozzle 62 includes a nozzle aperture 63. Nozzle 62 can be formed from silicon carbide or titanium.

Liquid material 53 can flow from crucible cavity 57, through trough 670 and be discharged through an opening or nozzle aperture 63 in the form of a liquid stream 35. After being discharged from nozzle aperture 63, liquid stream 35 travels onto substrate cylinder 26 (FIG. 1) where it cools and solidifies to form deposited stream 35. Deposited stream 35 can have the shape of a narrow line on substrate 26. Insulation 66 can cover case 55 and can insulate the case from the external environment.

An impeller 70 can be located in crucible cavity 57. Impeller 70 can include a rod 71 and ends 72 and 73. Impeller 70 can be formed from silicon carbide, titanium, ceramics or other suitable materials. Rod 71 extends upwardly through hole 69 in case 55. Rod 71 can be raised and lowered by an adjustment mechanism such as threaded rods 686 (see FIG. 5). A mixing bar or slinger 74 is attached to rod 71 in crucible cavity 57. Slinger 74 can mix liquid material 53 in crucible 56 when impeller 70 is rotated. Rod end 73 has a pintle 680 that extends into trough 670. Pintle 680 has a tip 682 and a mating surface 684. Mating surface 684 mates with seat 672 in order to stop the flow of the liquid material through the nozzle. Tip 682 also can seal nozzle aperture 63 stopping the flow of liquid material.

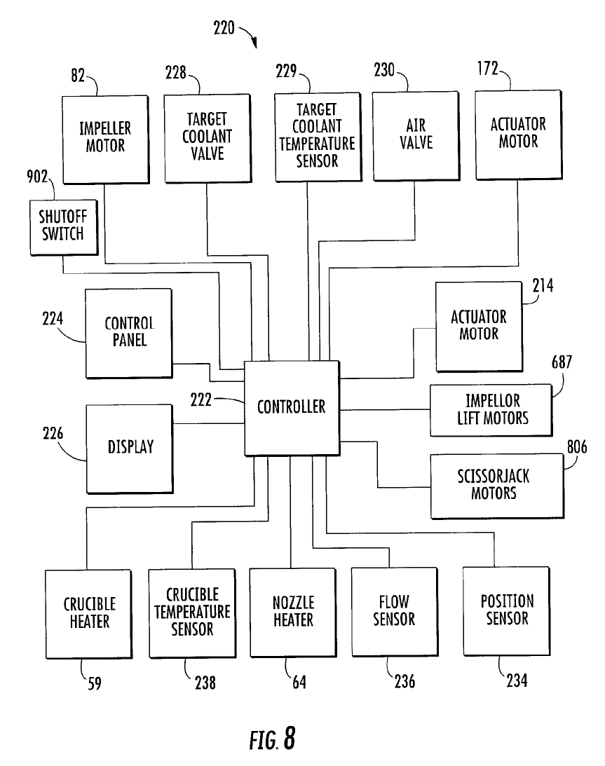

The rate of discharge of liquid material 53 can be controlled by the setting of threaded rods 686. Turning threaded rods 686 raises or lowers impeller 70 in crucible 56. A pair of rotary impeller lift motors 687 are mounted to threaded rods 686 and are in communication with a controller 222 (FIG. 8). Motors 687 can turn threaded rods 686 and therefore raise or lower impeller 70 in crucible 56. Impeller 70 further has cooling vanes 75 that are mounted in upper case 102. Plate 77 is attached to rod end 72.

An impeller drive assembly 80 can be connected to impeller 70 for rotating impeller 70. Impeller drive assembly 80 is mounted over furnace case 55. Impeller drive assembly 80 can include a rotary electric motor 82, plates 77 and 89, coupler 88, upper bearing block 90 and lower bearing block 92. Electric motor 82 may be mounted to plate 83. Plate 83 is attached to threaded rods 686. One end of rods 686 are attached to upper case top 102A. An output shaft 82A of electric motor 82 is connected to a plate 89. Coupler 88 is connected between plate 77 and plate 89. Plate 77 may be connected with impeller 70. Coupler 88 is made from an insulating material and prevents heat transfer from the hot impeller to the electric motor.

An upper bearing block 90 and lower bearing block 92 can contain bearings for rotatably supporting impeller 70. Electric motor 82 can rotate impeller 70 which mixes liquid material 53. Upper bearing block 90 is mounted to upper case top 102A and lower bearing block 92 is mounted in case bottom 102B.

An impeller cooling assembly 100 can be mounted inside case 102. Case 102 has a top 102A and bottom 102B. Case 102 can be mounted over furnace case 55. Cavity 87 is located between bottom 102B and case 55. Impeller cooling assembly 100 may include several passages 104, upper tube 106, bottom tube 108, air inlet 110, air outlet 112, stationary vanes 114 and movable vanes 75. Passages 104 form a snake like path inside case 102 between upper tube 106 and bottom tube 108. Air inlet 110 is connected to upper tube 106 and air outlet 112 is connected to bottom tube 108. Several movable vanes 75 are connected to rod 71 and extend into passages 104. Several stationary vanes 114 are connected to case 102 and extend into passages 104. Vanes 75 and 114 are arranged in an alternating manner inside case 102. Air inlet 110 is adapted to be connected with a source of pressurized air such as an air compressor.

Cool intake air flows into air inlet 110 and through passages 104. The air cools moveable vanes 75 and rod 71 as the air flows through passages 104. Warm exhaust air is exhausted through air outlet 112. Since, the impeller is immersed in liquid material 53, a large amount of heat is conducted along rod 71 toward end 72. Impeller cooling assembly 100 cools rod end 72 preventing heat transfer to motor 82.

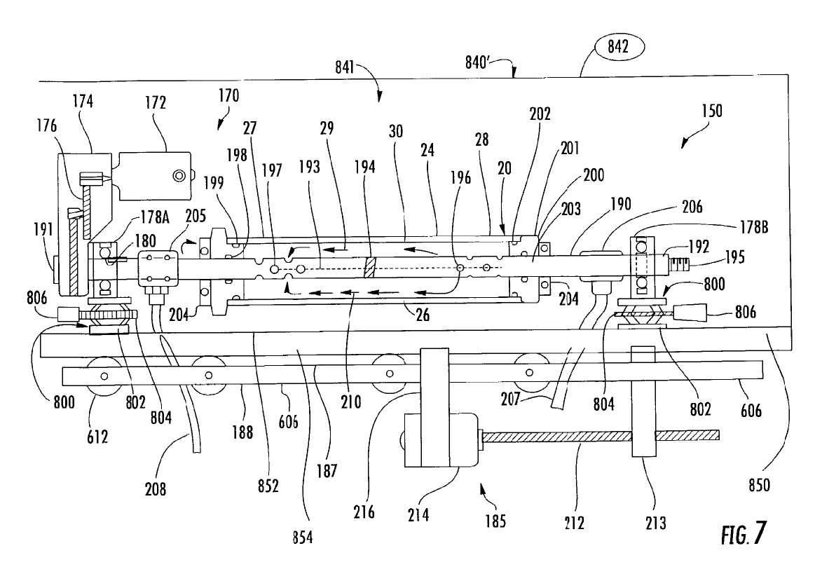

Turning now to FIGS. 5 and 7, a positioning mechanism or actuator assembly 150 is shown. Positioning mechanism or actuator assembly 150 can be mounted within housing 840 and move under crucible assembly 52. In FIG. 7, the target cooling housing 151 is removed in order to show further details. Actuator assembly 150 can hold and move sputtering target 20 adjacent to nozzle 62. Actuator assembly 150 can comprise a rotary actuator assembly or positioning mechanism 170, a translational actuator assembly or positioning mechanism 185 and a lift actuator assembly or positioning mechanism 800. The rotational actuator assembly 170 produces rotary motion between the target substrate and the nozzle. Rotational actuator assembly 170 can rotate the target substrate about the axis of rotation 32. The translational actuator assembly 185 is configured to produce linear motion between the substrate and the nozzle. Translational actuator assembly 185 can move the target substrate in a plane that is parallel to the longitudinal axis of the target substrate.

Actuator assembly 150 can include a target cooling housing 151 for cooling the outer surface of the sputtering target. Target cooling housing 151 can be mounted inside cavity 841 of housing 840. Crucible assembly 52 can be mounted on top plate 610. Target cooling housing 151 can have a cavity 152, gas passages 154, gas inlet 156, exhaust gas port 158, fluid passages 160, fluid inlet 162 and fluid outlet 164. Target substrate 26 is supported inside cavity 152 such that the substrate is partially surrounded by housing 151. Substrate 26 can be rotated and translated within cavity 152. Target cooling housing 151 can be made of a metal that has a high rate of heat transfer such as steel.

A source of pressurized gas can be connected to gas inlet 156. The gas flows through passages 154 and out of exhaust ports 158 where it impinges on target 20 and provides cooling to outer surface 24. The exhaust ports are arranged around cavity 152 such that the target can be uniformly cooled. An inert gas such as liquid nitrogen can be used to cool the target. A flexible sealing material 875 can be mounted to top plate 610 and extends toward enclosure sides 843. Flexible sealing material 875 can just touch sides 843. Sealing material 875 assists in retaining the air or inert gases within cavity 841.

Alternatively, other gases such as air or argon can be used to cool the target. The volume of gas exiting ports 158 can be controlled such that the rate of cooling of deposited material 22 on target 20 can be controlled. This allows for various parameters of deposited material 22 to be controlled such as grain size, alloy phase, crystal shape and surface texture.

In one embodiment, jets of gas can be used that are directed towards the target substrate in order to rapidly cool the deposited material and retain the material mixture. If the material is allowed to cool slowly, different components of the deposited material may separate.

A source of pressurized cooling fluid such as water can be connected to fluid inlet 162. The cooling fluid flows through fluid passages 160 and out of fluid outlet 164. The cooling fluid cools housing 151 and the air passing through passages 154.

Actuator assembly 150 further includes a rotary actuator mechanism 170 for rotating target substrate 26. Actuator mechanism 170 can include a hollow shaft 190 that is rotated by a variable speed motor 172 through a speed reducer 174. Alternatively, motor 172 could be used with a driving pulley, a driven pulley and a belt. Target 20 can be rotatably supported in cavity 152 by a hollow shaft 190. Shaft 190 can be formed from steel. Shaft 190 passes completely through bore 29. Shaft 190 has ends 191 and 192 and an inner bore 193. End 191 is sealed. Ends 191 and 192 are rotatably supported by bearing blocks 178A and B. Bearing blocks 178A and B have apertures 180 that ends 191 and 192 pass through.

Hollow shaft 190 can further include a center plug 194, end plug 195, coolant feed holes 196 and coolant exit holes 197. Center plug 194 is mounted in the center of shaft 190. End plug 195 seals end 192. The coolant feed holes are in communication with bore 193 and are adapted to be connected to a source of cooling fluid in order to dissipate the heat generated by the liquid material being deposited on the target substrate.

Endplates 200 are mounted to ends 27 and 28 of substrate 26. Endplates 200 have a wide region 201 that abuts against substrate 26 and a narrow region 202 that extends into bore 29. The endplates 200 each have an aperture 203 that shaft 190 passes through. A rubber o-ring 198 is located around shaft 190 between shaft 190 and endplate 200. A rubber o-ring 199 is located around endplate 200 between endplate 200 and inner surface 30. O-rings 198 and 199 seal cooling fluid 210 inside bore 29 between endplates 200. Collars 204 are attached to shaft 190 adjacent endplates 200 in order to retain endplates 200 to substrate 26. Collars 204 can be two pieces that are attached by fasteners around shaft 190.

A rotary union 205 may be connected about shaft 190 toward end 191. Rotary union 206 can be connected about shaft 190 toward end 192. Inlet hose 207 is connected to rotary union 206 and outlet hose 208 is connected to rotary union 205. Rotary unions 205 and 206 allow shaft 190 to rotate and allow a cooling fluid 210 to be circulated through the rotary unions into bore 193. Cooling fluid 210 would be pumped into inlet hose 207, through rotary union 206 and bore 193, and then through coolant feed holes 196 into bore 29. After moving along bore 29 and removing heat from substrate 26, fluid 210 would exit through coolant exit holes 197, bore 193, rotary union 205 and outlet hose 208. Heated cooling fluid 210 can then be cooled by an external apparatus (not shown) before being re-circulated or used again.

With continuing reference to FIG. 7, a variable electric speed motor 172 is connected to a speed reducer 174. Speed reducer 174 includes gears 176 that are connected to motor 172. Gears 176 are further connected to shaft end 191. Variable speed electric motor 172 is adapted to rotate shaft 190 and target 20 at a desired rate of rotation.

Translational positioning mechanism or actuator assembly 185 can include bearing blocks 178A and 178B. Bearing blocks 178A and 178B are mounted to and can support shaft 190 within housing 151. Bearing block 178B can be connected to scissors jack 802. An end of threaded rod 212 may be engaged with threaded block 213. Threaded block 213 is attached to table 850. The other end of rod 212 is attached to a rotary electric motor 214. Motor 214 is held by a bracket 216 that is attached to beam 606.

The rotation of threaded rod 212 by motor 214 causes table 850 to linearly move or be translated along beam 606. Since, bearing blocks 178B is connected to table 850 and housing 840, the movement of bearing block 178B causes housing 840 and sputtering target 20 to move linearly along the length of beam 606. While a threaded rod and rotary motor were used to move the bearing blocks, a linear actuator or solenoid could also be used.

A pair of lift actuator assemblies or positioning mechanisms 800 is mounted to each end of shaft 190. Each lift actuator assembly 800 can include a scissors jack 802 that has a threaded shaft 804. Scissors jack 802 can be mounted between bearing blocks 178A, 178B and table 850. A rotary actuator 806 is connected with threaded shaft 804. Rotary actuator 806 can cause threaded shaft 804 to rotate which causes the scissors jack 802 to move up and down and moves target 20 toward or away from table 850. Rotary actuator 806 can be in communication with controller 222 (FIG. 8). Rotary actuator 806 can be used to adjust the distance between nozzle 62 and target 20

In an alternative embodiment, the crucible assembly could be moved and the sputtering target only rotates. The translational actuator could be connected with or support the crucible assembly and move the crucible assembly parallel to the longitudinal axis of the target.

Control System

Referring now to FIGS. 5 and 8, a control system 220 is shown that can control the operation of deposition apparatus 50 (see FIG. 5). Control system 220 is capable of automatically controlling the operation of deposition apparatus 50.

Control system 220 can include a controller 222. Controller 222 can be a wide variety of control devices such as a computer or a programmable logic controller. Controller 222 can further have a memory device or communication devices. Controller 222 can control a wide variety of operating parameters of deposition apparatus 50. Controller 222 is in communication with a control panel 224 and a display 226. Control panel 224 can allow an operator of deposition apparatus 50 to input various commands and settings. Display 226 can display various operating parameters, settings, data and sensor readings from apparatus 50. Display 226 can also provide a warning indicator in case deposition apparatus 50 encounters an operating error.

Controller 222 can further be in communication with impeller motor 82, impeller lift motors 687, scissor jack motor 806, crucible temperature sensor 238, crucible heater 59 and flow sensor 236. Controller 222 can control crucible heater 59 such that liquid material 53 is maintained at the proper temperature for being deposited. Crucible temperature sensor 238 provides the temperature of liquid material 53 to controller 222. Controller 222 can raise and lower and turn on impeller motor 82 after the liquid material has reached the proper temperature for being discharged through nozzle 62. Controller 222 can also turn impeller motor 82 off. A flow sensor 236 is mounted near nozzle 62 and senses the flow of material from nozzle 62 and provides controller 222 with an indication of the flow rate of material from nozzle 62. An optional nozzle heater 64 is shown in FIG. 8.

Controller 222 is also in communication with target coolant valve 228, target coolant temperature sensor 229 and air valve 230. Controller 222 can sense the temperature of the coolant using coolant temperature sensor 229. When the coolant reaches a pre-determined temperature, controller 222 can adjust target coolant valve 228 to adjust the flow rate and maintain a desired temperature of the coolant and substrate 26. Air valve 230 can be operated by controller 222 in order to cool target 20 as liquid material 53 is being deposited and maintain a desired temperature of outer surface 24.

Controller 222 can control actuator motor 172, actuator motor 214, scissor jack motor 806 and position sensor 234. Controller 222 causes actuator motor 172 to rotate target substrate 20. Scissor jack motor 806 adjusts the distance between target 20 and nozzle 62. At the same time, controller 222 can cause actuator motor 214 to move target substrate 20 back and forth along beam 606. Position sensor 234 can provide an electrical signal to controller 222 that indicates the position of target 20. A shut off switch 902 is in communication with controller 222 can shut down all of the operating systems of deposition apparatus 50 if desired.

Referring to FIGS. 1, 5 and 7, during the operation and use of deposition apparatus 50, crucible assembly 52 is stationary and actuator apparatus 150 rotates and translates target substrate 20 under nozzle 62 such that a deposited stream 35 of the liquid material 53 may be uniformly spread over outer surface 24 in a helical pattern 36.

The crucible discharges a stream of liquid material 35 from the nozzle that is applied to the surface of the substrate. The substrate can be located below the nozzle 62 of the crucible so that gravity draws or forces the stream of liquid material 35 onto the substrate. The rotational actuator 170 and the translational actuator 185 move the substrate so that the stream may be uniformly applied in a helix pattern 36 forming sputtering target 20. The overlapping portions of the helix pattern 36 may be laid close enough so that substantially all of the outer surface 24 of the substrate is covered by the deposited material.

Additional coats or layers of the deposited material may be applied over the first coat of material in order to build up any desired thickness of the material on the target. If desired, a layer of material may be removed in between the coats to prevent voids from forming or to ensure a uniform thickness of material on the target. A portion or layers of deposited material may be removed by various methods that are known in the art, such as using a fixed tool like lathe machining or by using laser ablation.

Method of Operation

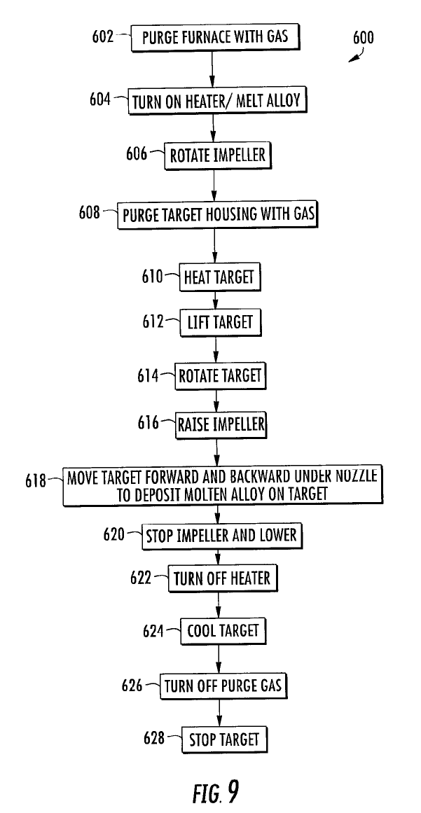

Turning now to FIG. 9, a method 600 of operating deposition apparatus 50 is shown. Method 600 includes purging cavity 55A with a gas at step 602. Furnace heaters 59 are turned on step 604 to melt the material in crucible 56. At step 606, impeller 70 is rotated by impeller drive assembly 80. At step 608, the target housing and cooling housing 151 are purged with a gas and cooling fluid is pumped. The target substrate 26 is also heated by the gas in step 610. At step 612, the target substrate 26 is lifted into position by lift actuator assembly 800. The target substrate 26 is rotated by actuator assembly 170 at step 614. At step 616, the impeller is raised such that the liquid material is discharged through the nozzle as a liquid material stream 35 onto the target substrate 26.

At step 618, if the target is moved forward and backward under the nozzle by actuator assembly 185 until the thickness of the deposited material 22 on the target substrate is of sufficient thickness. Next, method 600 proceeds to stop the rotation of impeller 70 and lower the impeller to stop the flow of liquid material through nozzle 62 at step 620. The heaters are turned off at step 622 and the target 20 is cooled at step 624. At step 626, the purge gas and cooling fluid are discontinued. At step 628, the rotation and translation of target 20 is stopped. The completed sputtering target may now be removed from the deposition apparatus.

First Alternative Crucible Assembly Embodiment

With specific reference to FIG. 10, crucible assembly 752 includes a crucible holder 54 that has an outer case 55 that contains a crucible 56. Case 55 can be formed from a metal such as steel. Crucible 56 would be formed from a heat resistant refractory material such as a ceramic, silicon carbide or graphite. Crucible 56 is cup shaped and has a crucible cavity 57. A crucible hole 57A is located at the bottom of crucible 56. A heat conductive thermal media 58 surrounds crucible 56.

The crucible assembly is constructed to withstand relatively high temperatures. For instance, the crucible assembly may withstand temperatures exceeding 1,100 degrees Celsius. Crucible 56 is adapted to hold a liquid material 53 in a liquid state.

At least one heat source 59 is provided for keeping the liquid material 53 at an operating temperature. The operating temperature is generally above the melting temperature of the material and it provides the liquid material with predetermined properties, such as viscosity.

In some embodiments, it may be desirable to control the atmosphere above liquid material 53 in order to further control unwanted elements in the liquid material such as oxygen or hydrogen. In these embodiments, all or part of deposition apparatus 50 may be placed in to a controlled atmosphere chamber (not shown). The chamber can be filled with a desired inert gas or vacuum to displace or remove the unwanted gases.

Heat source 59 can comprise several electric heaters that are arranged around crucible 56. The electric heaters are adapted to be connected with a source of electrical power. Thermal media 58 forms a path for heat transfer between the electric heaters and crucible 56. Heat source 59 can also be a heat transfer device such as a heat exchanger or a furnace.

A discharge tube 60 can be located below crucible 56 and is connected with crucible hole 57A. A port 61 extends through case 55 and is connected with discharge tube 60. A discharge opening such as a nozzle 62 is attached to case 55 by threads. Nozzle 62 includes a nozzle aperture 63 and nozzle heaters 64.

Liquid material 53 can flow from crucible cavity 57 through discharge tube 60, port 61 and nozzle 62 where the liquid material can be discharged through nozzle aperture 63 in the form of a liquid stream 35. Nozzle heaters 64 keep liquid material 53 in a liquid state and prevent any solidification of material 53 in nozzle 62. After being discharged from nozzle 62, liquid stream 35 travels onto substrate cylinder 26 (FIG. 1) where it forms deposited stream 35.

Insulation 66 covers case 55 and insulates the case 56 from the external environment. A cover 67 is located over case 55, thermal media 58 and crucible 56. Cover 67 is attached to case 55 by screws 68 and has a hole 69.

An impeller 70 can be located in crucible cavity 57. Impeller 70 can include a rod 71 and ends 72 and 73. Rod 71 extends upwardly through hole 69 in cover 67. A mixing bar or slinger 74 is attached to rod 71 in crucible cavity 57. Slinger 74 can mix liquid material 53 in crucible 56 when impeller 70 is rotated. Impeller 70 has threads 76 that are located toward end 73 on the outer surface of rod 71. Rod end 73 extends into discharge tube 60. As impeller 70 is rotated, threads 76 can force or move liquid material 53 through discharge tube 60 at a controlled rate to nozzle 62. The rate of discharge of liquid material 53 can be controlled by the rate of rotation of the impeller. Impeller 70 further has cooling vanes 75 that are mounted in upper case 102. Plate 77 is attached to rod end 72.

Second Alternative Crucible Assembly Embodiment

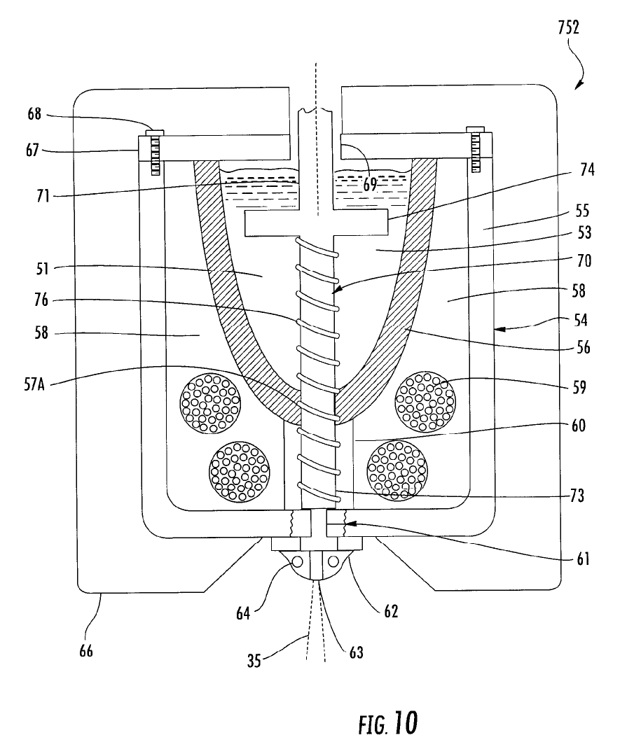

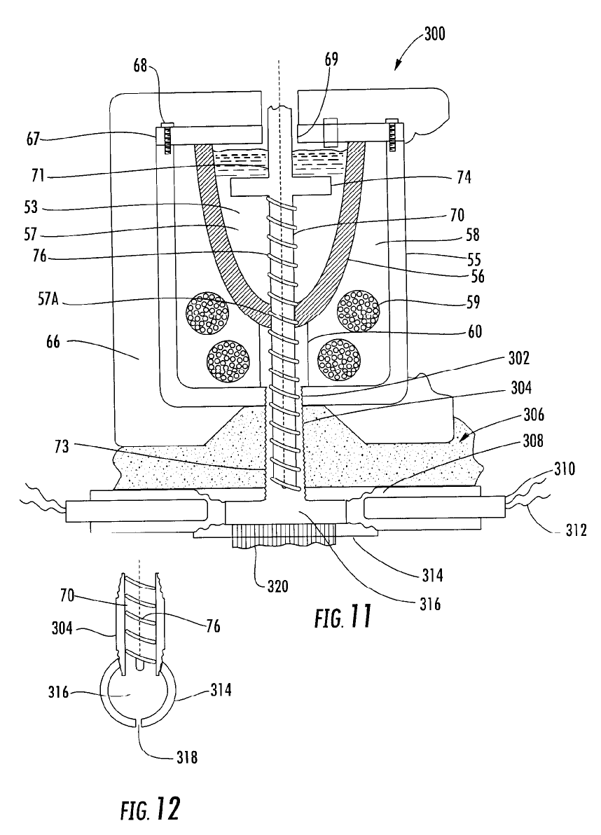

With reference to FIGS. 11 and 12, an alternative embodiment of a crucible assembly is shown. Crucible assembly 300 is similar to crucible assembly 752 previously described except that nozzle 62 has been replaced by a discharge pipe 304 that allows a liquid material ribbon 320 to be discharged onto the target substrate.

Crucible assembly 300 can include a discharge opening 302 and discharge pipe 304. Discharge pipe 304 is threaded into discharge opening 302. Impeller end 73 and threads 76 extend into discharge pipe 304. Spreader pipe 314 is connected to discharge pipe 304. Pipe plugs 308 are located in each end of and seal spreader pipe 314. Electric heaters 310 are mounted in pipe plugs 308 and can be connected to a source of electric power through heater wires 312. Heaters 310 keep the material in a liquid state in pipe 314. Spreader pipe 314 has a bore 316 that is in fluid communication with slot 318. Insulation 306 can be arranged around spreader pipe 314 and discharge pipe 304 in order to assist in keeping the material in a liquid state.

Crucible assembly 300 would operate in conjunction with actuator assembly 150 the same as previously described for deposition apparatus 50. Liquid material ribbon 320 would be discharged from slot 318 onto the substrate. As the substrate is rotated and translated, the liquid material ribbon would completely cover the substrate.

The use of crucible assembly 300 and liquid material ribbon 320 can result in the sputtering target being coated with a material in a shorter period of time than when liquid material stream 35 is used.

Third Alternative Crucible Assembly Embodiment

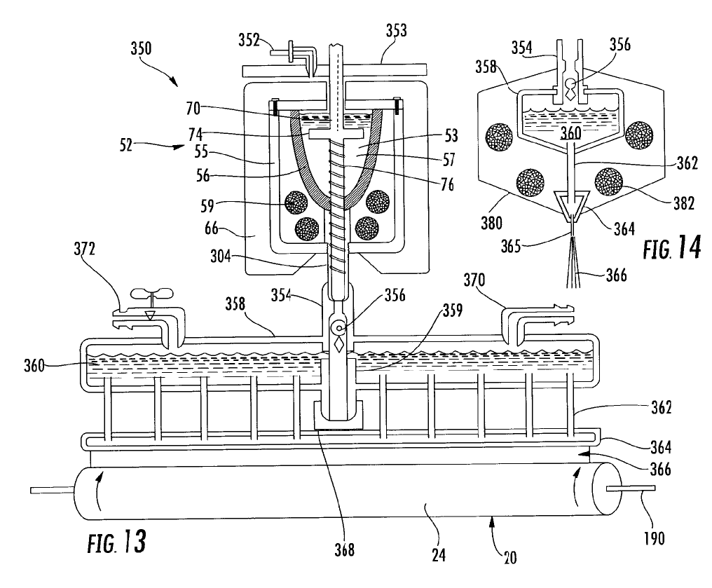

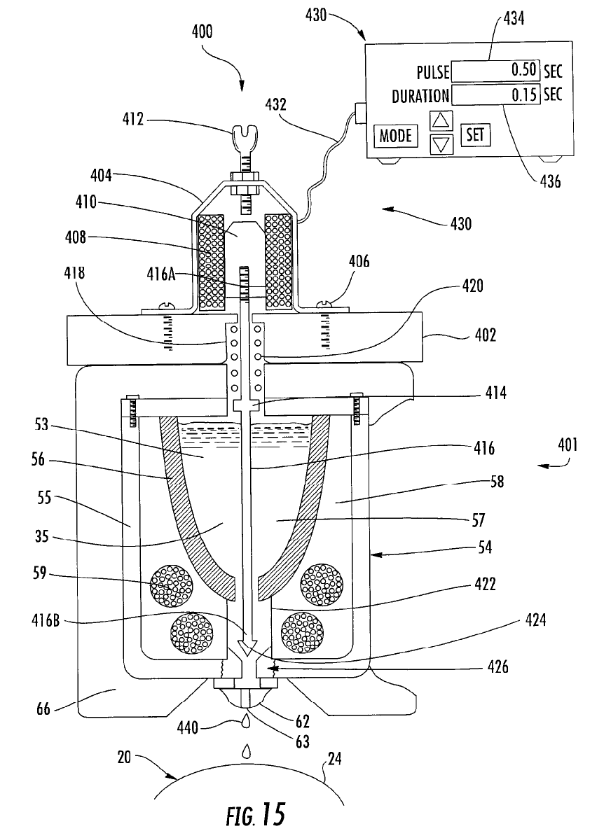

With reference now to FIGS. 13 and 14, another embodiment of a crucible assembly 350 is shown. Crucible assembly 350 is similar to crucible assembly 52 previously described except that nozzle 62 has been replaced with an accumulator tank 358 and slotted tube 364 that allows a continuous liquid material sheet 366 to be discharged onto the target substrate.

Crucible assembly 350 can include a gas inlet 352 that is connected to a top plate 353 and that is in communication with cavity 57. Gas inlet 352 can allow an inert gas to fill the space above liquid material 53. Gas inlet 352 can also allow a pressurized gas to be applied over liquid material 53. Crucible assembly 350 can further include a check valve 356 that is mounted inside check valve tube 354. Check valve tube 354 is connected with discharge pipe 304. An accumulator tank 358 is mounted below and connected to check valve tube 354. Accumulator tank 358 can hold a reservoir of liquid material 360.

Several capillary tubes 362 may be mounted below tank 358 and are further connected with a slotted tube 364. A slot 365 is located along the length of tube 364. Sediment trap 368 is mounted below check valve tube 354 and can contain any sediments that may flow through check valve 356.

A gas inlet 370 and gas outlet 372 are mounted to accumulator tank 358. Gas inlet 370 and outlet 372 can allow an inert gas to flow in the space above reservoir of material 360. Alternatively, gas inlet 370 can also allow a pressurized gas to be applied over reservoir of material 360 in order to control the flow rate of material sheet 366.

Housing 380 can be mounted around accumulator tank 358, capillary tubes 362 and slotted tube 364. Electric heaters 382 may be mounted in housing 380 in order to keep the liquid material in a liquid state.

Impeller end 73 and threads 76 can extend into discharge pipe 304. As impeller 70 is rotated, liquid material 53 is forced to flow through tube 354 and check valve 356 into tank 358 forming reservoir of material 360. Reservoir of material 360 then flows through capillary tubes 362, slotted tube 364 and is discharged through slot 365 as a continuous material sheet 366 onto the target substrate.

Crucible assembly 350 would operate in conjunction with rotary actuator assembly 170 in order to rotate the substrate. Since material sheet 366 is deposited in a sheet that is the same width as the substrate, translational actuator assembly 185 is not needed and may be omitted. As the target substrate is rotated, the liquid material sheet would completely cover the substrate.

The use of crucible assembly 350 and liquid material sheet 366 can result in sputtering target 20 being coated with material in a shorter period time than when liquid material stream 35 is used.

Fourth Alternative Crucible Assembly Embodiment

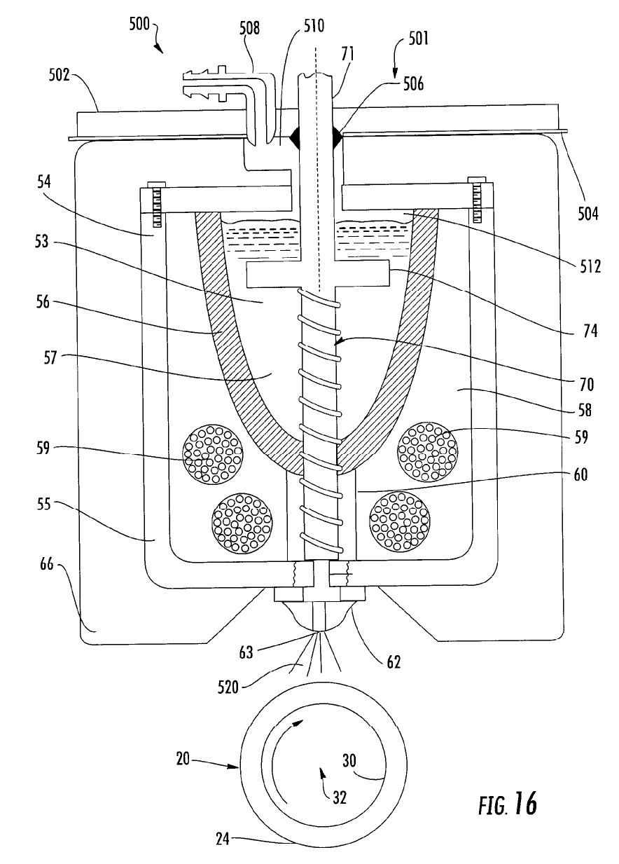

Referring to FIG. 15, still another embodiment of a crucible assembly 400 is shown. Crucible assembly 400 is similar to crucible assembly 52 previously described except that a drip control assembly 401 has been added that allows drops 440 of the liquid material to be discharged onto substrate 26.

Crucible assembly 400 can include drip control assembly 401 that has a cover 402 that is mounted over insulation 66 and crucible holder 54. Drip control assembly 401 may include a solenoid housing 404 that is mounted to cover 402 by screws 406 and a solenoid 408 that is mounted inside housing 404. Plunger 410 can be mounted inside solenoid 408. Plunger 410 may be made of a ferromagnetic material and can be magnetically coupled with solenoid 408.

A screw 412 is mounted to housing 404 and extends to contact plunger 410. Screw 412 can be adjusted in order to limit the travel distance of plunger 410. Spring cavity 418 is located in cover 402. Rod 416 has ends 416A and 416B. End 416A is mounted to plunger 410 and end 416B is connected to pintle 424. Spring stop 414 is located on rod 416. Spring 420 is mounted in spring cavity 418 and is retained by spring stop 414. Discharge tube 422 is connected to the bottom of crucible 56. Seat 426 may be mounted in discharge tube 422. Pintle 424 mates with seat 426 in order to stop the flow of liquid material 35 through nozzle 62.

Solenoid 408 can move rod 416 up and down and can move pintle 424 into and out of seat 426. In this manner, solenoid 408 can control the flow of the liquid material. Spring 420 biases pintle 424 into seat 426 when solenoid 408 is de-energized therefore stopping the flow of the liquid material.

A solenoid control 430 is connected to solenoid 408 through wire 432. Solenoid control 430 has a pulse time meter 434 and duration meter 436. Solenoid control 430 can control activation and de-activation of solenoid 408. Solenoid control 430 can be programmed to hold pintle 424 open for a duration of time and to keep pintle 424 closed for a pulse time period.

Nozzle 62 is connected with seat 426 and has a nozzle aperture 63. Drops 440 can be discharged from nozzle aperture 63 onto target 20.

Crucible assembly 400 would operate in conjunction with actuator assembly 150 the same as previously described for deposition apparatus 50. Liquid material drops 440 would be discharged from nozzle aperture 63 onto the target. As substrate 26 is rotated and translated, the liquid material drops 440 can cover the substrate.

Fifth Alternative Crucible Assembly Embodiment

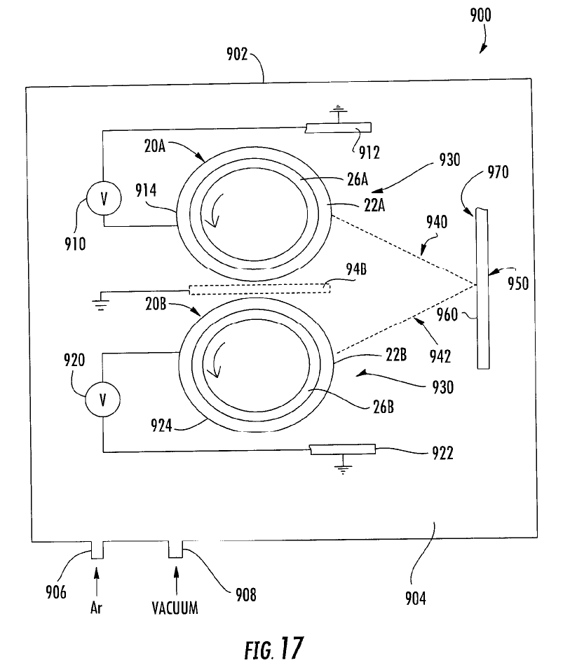

Referring to FIG. 16, another embodiment of a crucible assembly 500 is shown. Crucible assembly 500 is similar to crucible assembly 752 previously described except that pressure control assembly 501 has been added that allows the pressure applied above liquid material 53 to be regulated. Pressure control assembly 501 causes a liquid material spray 520 to be discharged onto substrate 26.

Pressure control assembly 501 can include a cover 502 that is mounted over insulation 66 and crucible holder 54. Gasket 504 can form a seal between insulation 66 and cover 502. Seal 506 is located around rod 71 and forms an airtight seal. Pressure control assembly 501 may include pressure port 508 and a passage 510 that are in communication with a space 512 above liquid material 53. Pressure port 508 can allow a pressurized gas to be applied in space 512. The pressurized gas can assist in forcing liquid material 53 through nozzle 62 to be discharged as a spray 520 onto the target substrate. The pressurized gas can be an inert gas or may be air.

Crucible assembly 500 would operate in conjunction with actuator assembly 150 the same as previously described for deposition apparatus 50. Liquid material drops 440 would be discharged from nozzle aperture 63 onto the target substrate. As substrate 26 is rotated and translated, the liquid material drops 440 can cover the substrate.

It can be realized that certain embodiments of the present invention provide an apparatus for depositing an material onto a substrate. The present invention also provides a method for depositing an material onto a substrate.

It is noted that deposition apparatus 50 is not limited for use in manufacturing sputtering targets. Deposition apparatus 50 may be used for depositing any liquid material onto any substrate. For example, deposition apparatus 50 can be used to apply wear coatings on various substrates such as a hard material outer layer covering a softer ductile inner material.

Sputtering System

Referring to FIG. 17, a sputtering system 900 is shown. Sputtering system 900 can include a housing 902 that has a chamber 904, an Argon port 906 and a vacuum port 908. The vacuum port 908 can be connected with a vacuum pump (not shown) so that air may be removed from chamber 904 creating a vacuum. A gas, such as Argon gas, can be fed into chamber 904 through port 906 creating a low pressure Argon gas atmosphere.

Sputtering system 900 can further include a one or more sputtering targets 20A and 20B that are heated and supported for rotation in chamber 904. Sputtering target 20A has an outer layer of material 22A mounted over substrate 26A. Sputtering target 20B has an outer layer of material 22B mounted over substrate 26B. The details of targets 20A and 20B were previously discussed in FIG. 1

A power supply 910 can be connected between target 20A and an anode 912. Anode 912 can be formed from a suitable metal. When connected to power supply 910, target 20A forms a cathode 914. A power supply 920 can be connected between target 20B and an anode 922. Anode 922 can be formed from a suitable metal. When connected to power supply 920, target 20A forms a cathode 924.

When power supplies 910 and 920 apply a high voltage between the anodes and cathodes creating an electric field, a plasma 930 containing Argon ions is created. The argon ions are accelerated by the electric field and impact targets 20A and 20B causing atoms 940 of material 20A and atom 942 of material 20B to be ejected. The atoms 940 and 942 travel all over chamber 904. A portion of atoms 940 and 942 are deposited on carrier 950 and bond with carrier 950 forming a thin film 960 that is a combination of materials 22A and 22B. A baffle 948 may be mounted between targets 20A and 20B to reduce cross-contamination during sputtering.

Carrier 950 can be a sheet of metal such as stainless steel that is rolled and unrolled across the targets in order to create large areas of coated carriers. When the target materials 22A and 22B are properly selected and applied to carrier 950, film 960 and carrier 950 can form a solar cell 970 that is able to convert sunlight into electricity. Further details of the use of sputtering systems and sputtering targets to produce solar cells can be found in U.S. Pat. No. 6,974,976 to Hollars. The contents of which are herein incorporated by reference.

It has been found that the use of sputtering targets 20A and 20B, produced using the liquid material deposition process of the present invention, result in the production of solar cells that have increased efficiency due to better control of the stoichiometric proportions of materials 22A and 22B as they are deposited.

### CONCLUSION

It can thus be realized that certain embodiments of the present invention can provide an apparatus and method for manufacturing a sputtering target that can apply a wide variety of materials and compositions to a substrate.

Although the description above contains many specifications, these should not be construed as limiting the scope of the invention but as providing illustrations of some of present embodiments of this invention. Thus, the scope of the invention should be determined by the appended claims and their legal equivalents rather than by the examples given.

What is claimed is:

1. A sputtering target comprising:
A) a substrate having a surface; and
B) a material on the surface of the substrate, the material having solidified after having been deposited on the surface in a stream of liquid material.

2. The sputtering target of claim 1 wherein the material is a metal alloy.

3. The sputtering target of claim 1 wherein the material was deposited on the substrate in a narrow line.

4. The sputtering target of claim 3 wherein the substrate comprises a cylinder and the line forms a helical pattern on the cylinder.

5. The sputtering target of claim 1 wherein the substrate comprises a cylinder and the surface of the substrate comprises an outer surface of the cylinder.

6. The sputtering target of claim 1 wherein the substrate comprises a substantially planar surface.

7. The sputtering target of claim 1 wherein a portion of the material is removed from the substrate after the molten material has been solidified.

8. The sputtering target of claim 7 wherein the material was removed by rotating the substrate around an axis and applying a fixed tool.

9. The sputtering target of claim 1 further comprising an adhesion promoter between the substrate and the material.

10. The sputtering target of claim 1 wherein the material comprises at least one material selected from the following list:
A) copper;
B) indium;
C) gallium;
D) selenium; and
E) zinc.

11. A sputtering target comprising:
A) a material means for providing a target material in a sputtering process; and
B) a substrate means for supporting the material means, wherein the material means having solidified on the substrate means after having been deposited on the substrate means in a stream of liquid material.

12. The sputtering target of claim 11, further comprising an adhesion promoter means for promoting adhesion between the material and the substrate.

13. The sputtering target of claim 11, further comprising removal means for removing a portion of the material means from the substrate means.

14. The sputtering target of claim 11 wherein the material means comprises at least one material selected from the following list:
A) copper;
B) indium;
C) gallium;
D) selenium; and
E) zinc.

15. The sputtering target of claim 11, wherein the sputtering target is mounted in a sputtering system.

16. The sputtering target of claim 11, wherein the sputtering target is used to manufacture solar cells.

17. The sputtering target of claim 11, wherein the substrate means comprises a cylinder adapted for rotation.

18. A sputtering system, comprising:
A) a sputtering chamber;
B) a target in the chamber, the target comprising:
a) a substrate having a surface; and
b) a material on the surface of the substrate, the material having been deposited on the surface in liquid form;
C) a power supply;
D) an anode connected to the power supply;
E) a cathode formed by the target being connected to the power supply;
F) an inert gas in the chamber;

19. The sputtering system of claim 18, wherein the target comprises a cylinder.

20. The sputtering system of claim 18, wherein the target is supported for rotation in the chamber.

21. The sputtering system of claim 11 wherein the material comprises at least one material selected from the following list:
A) copper;
B) indium;
C) gallium;
D) selenium; and
E) zinc.

22. The sputtering system of claim 18, wherein a plasma is created between the anode and the cathode.

23. The sputtering system of claim 23, wherein the plasma causes the material to be ejected from the substrate and to be deposited as a film on the carrier.

24. The sputtering system of claim 23, wherein the film forms at least a portion of a solar cell.

25. The sputtering system of claim 23, wherein the gas is argon.
